(19) United States
(12) Patent Application Publication
(10) Pub. No.: US 2025/0273571 A1
(43) Pub. Date: Aug. 28, 2025

(54) BACKSIDE CONTACT FORMATION FOR A SEMICONDUCTOR DEVICE STRUCTURE WITH A DENSE GATE PITCH

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Kisik Choi, Watervliet, NY (US)

(21) Appl. No.: 18/588,195

(22) Filed: Feb. 27, 2024

(51) Int. Cl. H01L 23/528; H01L 21/768; H01L 27/088; H01L 29/40; H01L 29/417

(52) U.S. Cl. CPC H01L 23/5286; H01L 21/768; H10D 64/01; H10D 64/254; H10D 84/83

(57) ABSTRACT

A semiconductor device is provided and includes an active region, first, second and third gate regions disposed across the active region, a first source/drain (S/D) epitaxial region interposed between the first and second gate regions, a second S/D epitaxial region interposed between the second and third gate regions, backside metallization, a first backside contact to connect the first S/D epitaxial region to the backside metallization, a second backside contact to connect the second S/D epitaxial region to the backside metallization and backside insulation disposed to isolate the first and second backside contacts from one another.

### BACKGROUND

The present disclosure generally relates to fabrication methods and resulting structures for semiconductor devices. More specifically, the present disclosure relates to backside contact formation for a semiconductor device structure with a dense gate pitch.

A transistor is a semiconductor device used to amplify or switch electrical signals and power and is one of the basic building blocks of modern electronics. A field-effect transistor (FET) is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a semiconductor device is provided and includes an active region, first, second and third gate regions disposed across the active region, a first source/drain (S/D) epitaxial region interposed between the first and second gate regions, a second S/D epitaxial region interposed between the second and third gate regions, backside metallization, a first backside contact to connect the first S/D epitaxial region to the backside metallization, a second backside contact to connect the second S/D epitaxial region to the backside metallization and backside insulation disposed to isolate the first and second backside contacts from one another. In additional or alternative embodiments, the semiconductor device provides for two separate backside contacts between the backside metallization and each of the first and the second S/D epitaxial regions.

According to an aspect of the disclosure, a semiconductor device is provided and includes an active region, first, second and third gate regions disposed across the active region, a first source/drain (S/D) epitaxial region interposed between the first and second gate regions, a second S/D epitaxial region interposed between the second and third gate regions, first backside metallization, second backside metallization, a first backside contact to connect the first S/D epitaxial region to the first backside metallization, a second backside contact to connect the second S/D epitaxial region to the second backside metallization and backside insulation disposed to isolate the first and second backside contacts from one another. In additional or alternative embodiments, the semiconductor device provides for two separate backside contacts between the backside metallization and each of the first and the second S/D epitaxial regions.

According to an aspect of the disclosure, a semiconductor device fabrication method is provided and includes disposing first, second and third gate regions across an active region, interposing first and second source/drain (S/D) epitaxial regions between the first and second gate regions and between the second and third gate regions, respectively, forming an initial backside contact to connect the first and second S/D epitaxial regions to backside metallization, opening a contact cut through the initial backside contact to reform the initial backside contact as first and second backside contacts connected to the first and second S/D epitaxial regions, respectively, and filling the contact cut with insulation to isolate the first and second backside contacts from one another. In additional or alternative embodiments, the semiconductor device provides for two separate backside contacts between the backside metallization and each of the first and the second S/D epitaxial regions.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a top-down view of a semiconductor device in accordance with one or more embodiments;

FIG. 2 is a side view of the semiconductor device of FIG. 1 in accordance with one or more embodiments;

FIG. 3 is a flow diagram illustrating a semiconductor device fabrication method in accordance with one or more embodiments;

FIG. 4 is a side view of an initial semiconductor device structure in accordance with one or more embodiments;

FIG. 5 includes upper and lower images which are side views of secondary and tertiary semiconductor device structures in accordance with embodiments;

FIG. 6 is a side view of a fourth semiconductor device structure in accordance with one or more embodiments;

FIG. 7 is a side view of the semiconductor device of FIG. 1 in accordance with one or more embodiments;

FIG. 8 is a flow diagram illustrating a semiconductor device fabrication method in accordance with one or more embodiments;

FIG. 9 is a side view of a secondary semiconductor device structure in accordance with one or more embodiments;

FIG. 10 is a side view of a tertiary semiconductor device structure in accordance with embodiments; and

FIG. 11 is a side view of a fourth semiconductor device structure in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided and includes an active region, first, second and third gate regions disposed across the active region, a first source/drain (S/D) epitaxial region interposed between the first and second gate regions, a second S/D epitaxial region interposed between the second and third gate regions, backside metallization, a first backside contact to connect the first S/D epitaxial region to the backside metallization, a second backside contact to connect the second S/D epitaxial region to the backside metallization and backside insulation disposed to isolate the first and second backside contacts from one another. In additional or alternative embodiments, the semiconductor device provides for two separate backside contacts between the backside metallization and each of the first and the second S/D epitaxial regions.

In accordance with additional or alternative embodiments, the first and second S/D epitaxial regions are separated by a distance of about 48-54 nm or less and the backside insulation includes dielectric material centered between the first and second backside contacts. At 48-54 nm or less, it would be difficult to obtain the two separate backside contacts between the backside metallization and each of the first and the second S/D epitaxial regions.

In accordance with additional or alternative embodiments, the semiconductor device further includes a back-end-of-line (BEOL) layer, a carrier wafer disposed on the BEOL layer and a frontside contact to connect one of the first and second S/D epitaxial regions to the BEOL layer. The semiconductor device is thus compatible with complementary metal-oxide semiconductor (CMOS) technologies.

In accordance with additional or alternative embodiments, the backside metallization is one of a backside power rail (BPR) and a backside signal carrier. In either case, the two separate backside contacts provide for connections to the first and second S/D epitaxial regions.

In accordance with additional or alternative embodiments, the backside metallization is one of a VDD and a VSS signal carrier. In either case, the two separate backside contacts provide for connections to the first and second S/D epitaxial regions.

In accordance with additional or alternative embodiments, the semiconductor device further includes a backside interconnect layer, additional backside metallization disposed on the backside interconnect layer and connection metallization to connect the backside metallization and the additional backside metallization. This way, the semiconductor device can be integrated into a wafer-level design.

According to an aspect of the disclosure, a semiconductor device is provided and includes an active region, first, second and third gate regions disposed across the active region, a first source/drain (S/D) epitaxial region interposed between the first and second gate regions, a second S/D epitaxial region interposed between the second and third gate regions, first backside metallization, second backside metallization, a first backside contact to connect the first S/D epitaxial region to the first backside metallization, a second backside contact to connect the second S/D epitaxial region to the second backside metallization and backside insulation disposed to isolate the first and second backside contacts from one another. In additional or alternative embodiments, the semiconductor device provides for two separate backside contacts between the backside metallization and each of the first and the second S/D epitaxial regions.

In accordance with additional or alternative embodiments, the first and second S/D epitaxial regions are separated by a distance of about 48-54 nm or less and the backside insulation includes a dielectric liner surrounding one of the first and second backside contacts. At 48-54 nm or less, it would be difficult to obtain the two separate backside contacts between the backside metallization and each of the first and the second S/D epitaxial regions.

In accordance with additional or alternative embodiments, the semiconductor device further includes a back-end-of-line (BEOL) layer, a carrier wafer disposed on the BEOL layer and a frontside contact to connect one of the first and second S/D epitaxial regions to the BEOL layer. The semiconductor device is thus compatible with complementary metal-oxide semiconductor (CMOS) technologies.

In accordance with additional or alternative embodiments, the first and second backside metallization are each one of a backside power rail (BPR) and a backside signal carrier. In either case, the two separate backside contacts provide for connections to the first and second S/D epitaxial regions.

In accordance with additional or alternative embodiments, the first and second backside metallization are each one of a VDD and a VSS signal carrier. In either case, the two separate backside contacts provide for connections to the first and second S/D epitaxial regions.

In accordance with additional or alternative embodiments, the first and second backside metallization have different electrical potentials. In either case, the two separate backside contacts provide for connections to the first and second S/D epitaxial regions.

In accordance with additional or alternative embodiments, the semiconductor device further includes a backside interconnect layer on which the second backside metallization is disposed and connection metallization to connect the first backside metallization to the backside interconnect layer. This way, the semiconductor device can be integrated into a wafer-level design.

According to an aspect of the disclosure, a semiconductor device fabrication method is provided and includes disposing first, second and third gate regions across an active region, interposing first and second source/drain (S/D) epitaxial regions between the first and second gate regions and between the second and third gate regions, respectively, forming an initial backside contact to connect the first and second S/D epitaxial regions to backside metallization, opening a contact cut through the initial backside contact to reform the initial backside contact as first and second backside contacts connected to the first and second S/D epitaxial regions, respectively, and filling the contact cut with insulation to isolate the first and second backside contacts from one another. In additional or alternative embodiments, the semiconductor device provides for two separate backside contacts between the backside metallization and each of the first and the second S/D epitaxial regions.

In accordance with additional or alternative embodiments, the first and second S/D epitaxial regions are separated by a distance of about 48-54 nm or less and the opening of the contact cut includes opening the contact cut through a center of the initial backside contact. At 48-54 nm or less, it would be difficult to obtain the two separate backside contacts between the backside metallization and each of the first and the second S/D epitaxial regions.

In accordance with additional or alternative embodiments, the method further includes forming an alignment mark at a known distance from the center of the initial backside contact and identifying the center of the initial backside contact by reference to the alignment mark. This provides for precise location of the backside insulation.

In accordance with additional or alternative embodiments, the method further includes disposing a carrier wafer on a back-end-of-line (BEOL) layer and disposing a frontside contact to connect one of the first and second S/D epitaxial regions to the BEOL layer. The method is thus compatible with complementary metal-oxide semiconductor (CMOS) technologies.

In accordance with additional or alternative embodiments, the backside metallization is one of a backside power rail (BPR) and a backside signal carrier and/or a VDD and a VSS signal carrier. In either case, the two separate backside contacts provide for connections to the first and second S/D epitaxial regions.

In accordance with additional or alternative embodiments, the method further includes disposing additional backside metallization on a backside interconnect layer and disposing connection metallization to connect the backside metallization and the additional backside metallization. This way, the method is applicable to a wafer-level design.

In accordance with additional or alternative embodiments, the backside metallization and the additional backside metallization have different electrical potentials. In either case, the two separate backside contacts provide for connections to the first and second S/D epitaxial regions.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, in certain semiconductor device structures a distance between epitaxial regions (i.e., epi-to-epi distance) can be relatively short. Indeed, in such semiconductor device structures with a relatively dense gate pitch, the epi-to-epi distance can be about 48-54 nm. At this level of gate pitch density, it can be difficult to form contacts to backside power rails. In some cases, semiconductor device structures with a relatively dense gate pitch have only a single contact formed from one source/drain (S/D) epitaxial region to a backside power rail whereas a neighboring S/D epitaxial region may only be provided with a placeholder element that does not reach the backside power rail. In other cases, semiconductor device structures with a relatively dense gate pitch have a single, large contact that is formed from neighboring S/D epitaxial regions to a backside power rail.

Accordingly, there remains a need for an improved semiconductor device structure with a relatively dense gate pitch of 48-54 nm or less in which first and second contacts are provided for first and second neighboring S/D epitaxial regions, respectively, in order to connect the first and second neighboring S/D epitaxial regions to a same backside power rail or connect the first and second neighboring S/D epitaxial regions to different backside power rails with different voltage potentials.

Turning now to an overview of the aspects of the disclosure, one or more embodiments of the disclosure address the above-described shortcomings of the prior art by providing a semiconductor device with a relatively dense gate pitch of 48-54 nm or less. The semiconductor device with the relatively dense gate pitch includes first and second backside contacts for first and second neighboring S/D epitaxial regions, respectively. The first backside contact connects the first S/D epitaxial region to a backside power rail and the second backside contact connects the second S/D epitaxial region to the same backside power rail or to a different backside power rail (i.e., one to VDD and one to VSS or one to a power rail and one to a signal rail).

The above-described aspects of the disclosure address the shortcomings of the prior art by providing for a semiconductor device that includes an active region, first, second and third gate regions disposed across the active region, a first S/D epitaxial region interposed between the first and second gate regions and a second S/D epitaxial region interposed between the second and third gate regions. In one or more embodiments, the semiconductor device further includes backside metallization, a first backside contact to connect the first S/D epitaxial region to the backside metallization, a second backside contact to connect the second S/D epitaxial region to the backside metallization and backside insulation disposed to isolate the first and second backside contacts from one another. Alternatively, in one or more embodiments, the semiconductor device further includes first backside metallization, second backside metallization, a first backside contact to connect the first S/D epitaxial region to the first backside metallization, a second backside contact to connect the second S/D epitaxial region to the second backside metallization and backside insulation disposed to isolate the first and second backside contacts from one another.

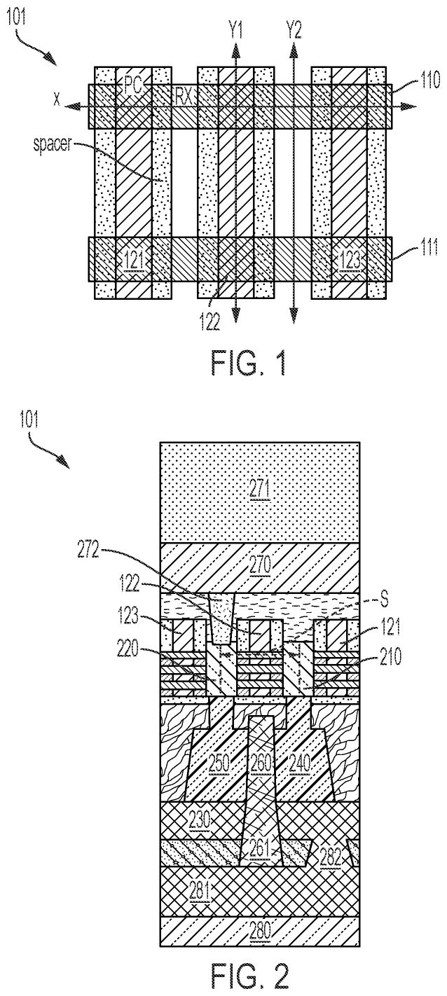

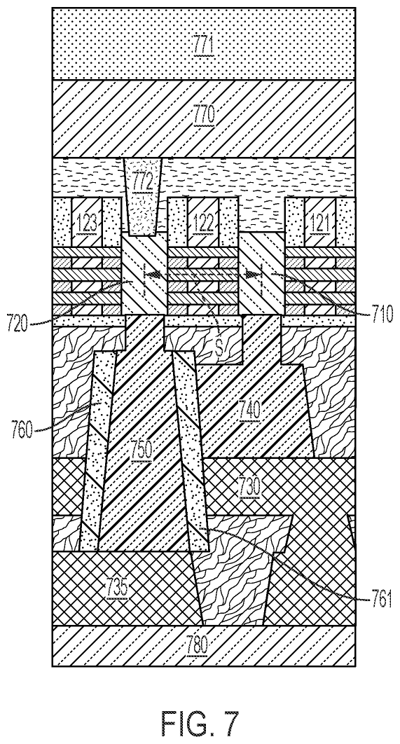

Turning now to a more detailed description of aspects of the present disclosure, FIG. 1 depicts a top-down view of a semiconductor device 101. FIG. 2 and FIGS. 4-6 are side views of the semiconductor device 101 in accordance with one or more embodiments and are each taken from a perspective defined by cross-sectional view X of FIG. 1. FIG. 7 and FIGS. 9-11 are side views of the semiconductor device 101 in accordance with one or more alternative embodiments and are each taken from the perspective defined by cross-sectional view X of FIG. 1.

As shown in FIG. 1, the semiconductor device 101 includes first and second active regions 110 and 111 and first gate region 121, second gate region 122 and third gate region 123. The first gate region 121 is disposed across the first and second active regions 110 and 111, the second gate region 122 is disposed across the first and second active regions 110 and 111 and the third gate region 123 is disposed across the first and second active regions 110 and 111.

As shown in FIGS. 1 and 2 and in accordance with one or more embodiments, the semiconductor device 101 further includes a first S/D epitaxial region 210 that is electrically and structurally interposed between the first gate region 121 and the second gate region 122, a second S/D epitaxial region 220 that is electrically and structurally interposed between the second gate region 122 and the third gate region 123, backside metallization 230, a first backside contact 240, a second backside contact 250 and backside insulation 260. The backside metallization 230 can be provided as one of a backside power rail (BPR) and a backside signal carrier and/or as one of a VDD and a VSS signal carrier. The first backside contact 240 is disposed to electrically connect the first S/D epitaxial region 210 to the backside metallization 230 and the second backside contact 250 is disposed to electrically connect the second S/D epitaxial region 220 to the backside metallization 230. The backside insulation 260 is disposed to electrically isolate the first backside contact 240 and the second backside contact 250 from one another.

The semiconductor device 101 of FIGS. 1 and 2 can further include a back-end-of-line (BEOL) layer 270, a carrier wafer 271 that is disposed on the BEOL layer 270 and a frontside contact 272 that is disposed to electrically connect one of the first S/D epitaxial region 210 and the second S/D epitaxial region 220 to the BEOL layer 270. In addition, the semiconductor device 101 of FIGS. 1 and 2 can also include a backside interconnect layer 280, additional backside metallization 281 that is disposed on the backside interconnect layer 280 and connection metallization 282 to electrically connect the backside metallization 230 and the additional backside metallization 281.

The semiconductor device 101 of FIGS. 1 and 2 can be characterized as having a relatively dense gate pitch in which the first S/D epitaxial region 210 and the second S/D epitaxial region 220 are separated from one another by a separation distance S of about 48-54 nm or less. In these or other cases, the backside insulation 260 can include a pillar of dielectric material 261 and can be substantially centered between the first backside contact 240 and the second backside contact 250.

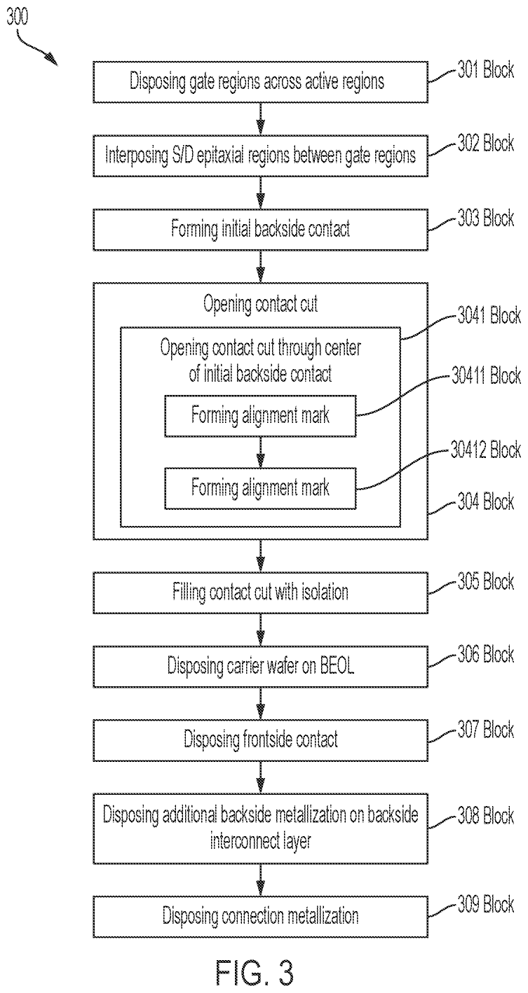

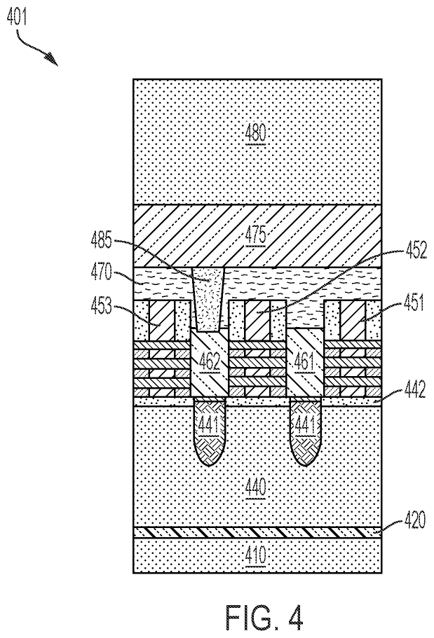

With reference to FIG. 3 and with additional reference to FIGS. 4-6, a semiconductor device fabrication method 300 is provided to form the semiconductor device 101 of FIGS. 1 and 2. As noted above, FIGS. 4-6 are each taken from the perspective defined by cross-sectional view X of FIG. 1.

As shown in FIG. 3, the semiconductor device fabrication method 300 includes disposing first, second and third gate regions across an active region (block 301), interposing first and second source/drain (S/D) epitaxial regions, which are separated by a distance of about 48-54 nm or less, between the first and second gate regions and between the second and third gate regions, respectively, (block 302) and forming an initial backside contact to connect the first and second S/D epitaxial regions to backside metallization (block 303). The backside metallization can be provided as one of a backside power rail (BPR) and a backside signal carrier and/or a VDD and a VSS signal carrier. The semiconductor device fabrication method 300 can further include opening a contact cut through the initial backside contact to reform the initial backside contact as first and second backside contacts connected to the first and second S/D epitaxial regions, respectively, (block 304) and filling the contact cut with isolation, such as dielectric material, to isolate the first and second backside contacts from one another (block 305).

In addition, as shown in FIG. 3, the semiconductor device fabrication method 300 also includes disposing a carrier wafer on a back-end-of-line (BEOL) layer (block 306) and disposing a frontside contact to connect one of the first and second S/D epitaxial regions to the BEOL layer (block 307) as well as disposing additional backside metallization on a backside interconnect layer (block 308) and disposing connection metallization to connect the backside metallization and the additional backside metallization (block 309) where the backside metallization and the additional backside metallization have different electrical potentials.

In accordance with one or more embodiments, the opening of the contact cut of block 304 can include opening the contact cut through a center of the initial backside contact (block 3041) by, for example, forming an alignment mark at a known distance from the center of the initial backside contact (block 30411) and identifying the center of the initial backside contact through intervening layers (i.e., a metallization layer and/or a hard mask layer) by reference to the alignment mark (block 30412).

As shown in FIG. 4, an initial semiconductor device structure 401 is provided in an initial stage of assembly and includes a first semiconductor substrate 410, a second semiconductor substrate 420 and a third semiconductor substrate 440. The third semiconductor substrate 440 is formed to define recesses in which placeholder elements 441 are disposed and has an upper surface on which bottom dielectric isolation (BDI) 442 is deposited. First, second and third gate regions 451, 452 and 453 are formed over the BDI 442, first S/D epitaxial region 461 is electrically and structurally interposed between the first and second gate regions 451 and 452 and second S/D epitaxial region 462 is electrically and structurally interposed between the second and third gate regions 452 and 453. Interlayer dielectric (ILD) 470 is deposited on the first, second and third gate regions 451, 452 and 453 and on the first and second S/D epitaxial regions 461 and 462. A BEOL layer 475 is formed on the ILD 470 and a carrier wafer 480 is disposed on the BEOL layer 475. A frontside contact 485 is disposed to electrically connect the second S/D epitaxial region 462 and the BEOL layer 475 to one another.

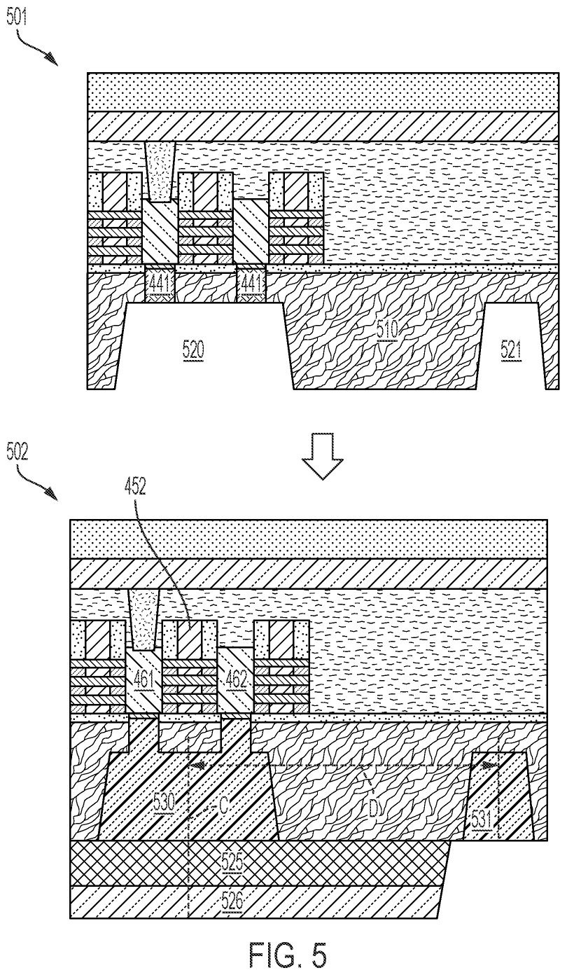

As shown in FIG. 5, the upper image is that of a secondary semiconductor device structure 501 provided in a secondary stage of assembly following frontside substrate removal processes, backside ILD deposition to form backside ILD 510, chemical mechanical polishing (CMP) and backside contact patterning executed with respect to the initial semiconductor device structure 401 of FIG. 4. The backside contact patterning forms a backside contact opening 520 and a backside alignment mark opening 521 by backside contact reactive ion etching (RIE). The lower image is that of a tertiary semiconductor device structure 502 provided in a tertiary stage of assembly following removal of the placeholder elements 441 of FIG. 4, initial backside contact formation and sequential deposition of backside metallization 525 and hard mask material 526 executed with respect to the secondary semiconductor device structure 501. The initial backside contact formation results in the formation of an initial backside contact 530, which is disposed in contact with the first and second S/D epitaxial regions 461 and 462. The initial backside contact formation also results in the formation of an alignment mark contact 531, which can include an alignment mark. A distance D between the alignment mark contact 531 and a center C of the initial backside contact 530 is known. The center C of the initial backside contact 530 may be generally aligned with replacement metal gate material of the second gate region 452. The backside metallization 525 and the hard mask material 526 cover the initial backside contact 530 but do not cover the alignment mark contact 531. Thus, a location of the center C of the initial backside contact 530 can be identified through the backside metallization 525 and the hard mask material 526 and any other intervening layers by reference to the alignment mark contact 531.

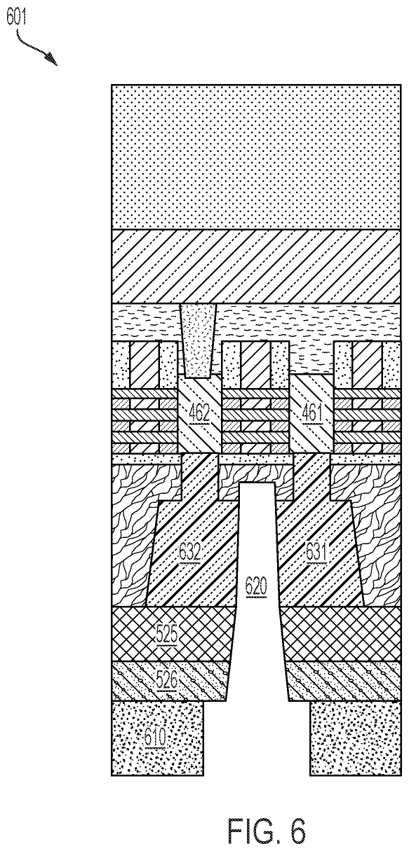

As shown in FIG. 6, a fourth semiconductor device structure 601 is provided in a fourth stage of assembly following backside metallization backside patterning, formation of an organic planarization layer (OPL) 610 and a self-aligned backside contact cut executed with respect to the tertiary semiconductor device structure 502 of the lower image of FIG. 5. A location of the self-aligned backside contact cut is executed by reference to the alignment mark contact 531 of the lower image of FIG. 5 and forms a contact cut opening 620 by RIE that extends through the OPL 610, the hard mask material 526, the backside metallization 525 and the initial backside contact 530 of the lower image of FIG. 5 to thus reform at least the initial backside contact into a first backside contact 631 and a second backside contact 632. The first backside contact 631 is disposed to electrically connect the first S/D epitaxial region 461 to the backside metallization 525 and the second backside contact 632 is disposed to electrically connect the second S/D epitaxial region 462 to the backside metallization 525.

The semiconductor device 101 of FIG. 2 can subsequently be arrived at by backside ILD fill and CMP to form the pillar of the dielectric material 261 of the backside insulation 260 in the contact cut opening 620 of FIG. 6 as well as formation of the connection metallization 282, the additional backside metallization 281 and the backside interconnect layer 280 executed with respect to the fourth semiconductor device structure 601 of FIG. 6.

As shown in FIGS. 1 and 7 and in accordance with one or more embodiments, the semiconductor device 101 further includes a first S/D epitaxial region 710 that is electrically and structurally interposed between the first gate region 121 and the second gate region 122, a second S/D epitaxial region 720 that is electrically and structurally interposed between the second gate region 122 and the third gate region 123, first backside metallization 730, second backside metallization 735, a first backside contact 740, a second backside contact 750 and backside insulation 760. Each of the first backside metallization 730 and the second backside metallization 735 can be provided as one of a backside power rail (BPR) and a backside signal carrier and/or as one of a VDD and a VSS signal carrier and/or as having different electrical or voltage potentials. The first backside contact 740 is disposed to electrically connect the first S/D epitaxial region 710 to the first backside metallization 730 and the second backside contact 750 is disposed to electrically connect the second S/D epitaxial region 720 to the second backside metallization 735. The backside insulation 760 is disposed to electrically isolate the first backside contact 740 and the second backside contact 750 from one another.

The semiconductor device 101 of FIGS. 1 and 7 can further include a BEOL layer 770, a carrier wafer 771 that is disposed on the BEOL layer 770 and a frontside contact 772 that is disposed to electrically connect one of the first S/D epitaxial region 710 and the second S/D epitaxial region 720 to the BEOL layer 770. In addition, the semiconductor device 101 of FIGS. 1 and 7 can also include a backside interconnect layer 780 on which the second backside metallization 735 is disposed and connection metallization 782 to electrically connect the first backside metallization 730 and the backside interconnect layer 780.

The semiconductor device 101 of FIGS. 1 and 7 can be characterized as having a relatively dense gate pitch in which the first S/D epitaxial region 710 and the second S/D epitaxial region 720 are separated from one another by a separation distance S of about 48-54 nm or less. In these or other cases, the backside insulation 760 can include a dielectric liner 761 that surrounds one of the first backside contact 740 and the second backside contact 750.

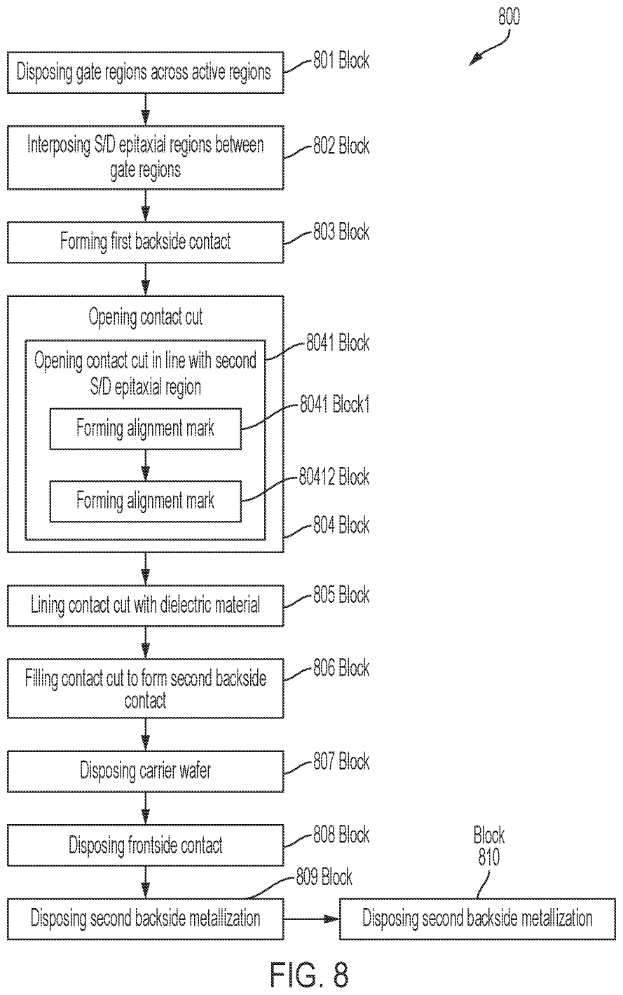

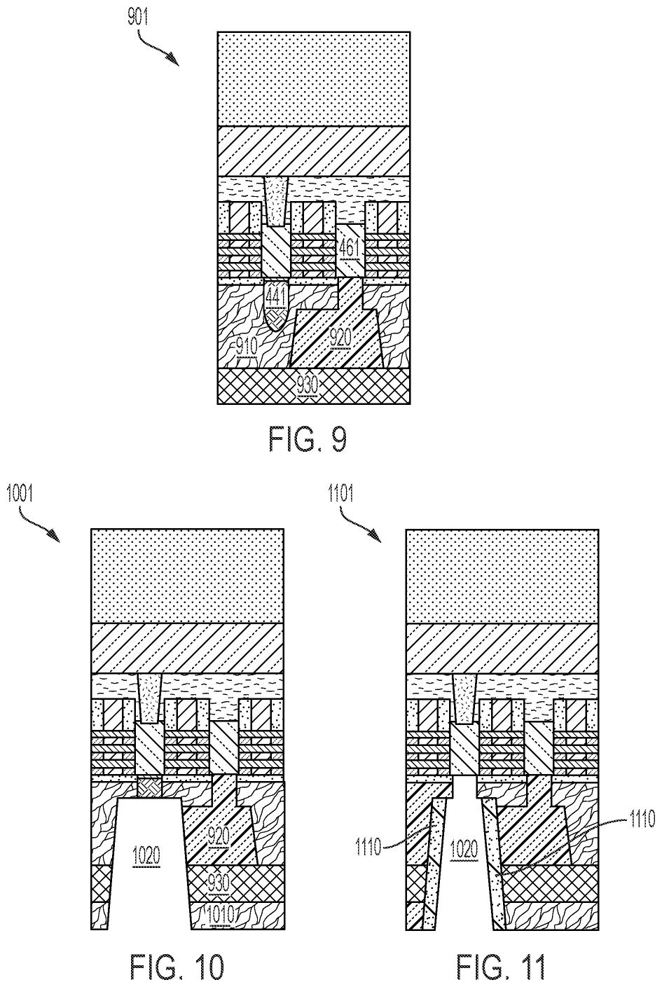

With reference to FIG. 8 and with additional reference to FIGS. 9-11, a semiconductor device fabrication method 800 is provided to form the semiconductor device 101 of FIGS. 1 and 7. As noted above, FIGS. 9-11 are each taken from the perspective defined by cross-sectional view X of FIG. 1.

As shown in FIG. 8, the semiconductor device fabrication method 800 includes disposing first, second and third gate regions across an active region (block 801), interposing first and second source/drain (S/D) epitaxial regions, which are separated by a distance of about 48-54 nm or less, between the first and second gate regions and between the second and third gate regions, respectively, (block 802) and forming a first backside contact to connect the first S/D epitaxial region to first backside metallization (block 803). The semiconductor device fabrication method 800 can further include opening a contact cut through the first backside metallization (block 804), lining the contact cut with dielectric material to form a dielectric liner as backside insulation (block 805), filling the contact cut to form a second backside contact to connect the second S/D epitaxial region to second backside metallization (block 806). The first and second backside metallization can be provided as one of a backside power rail (BPR) and a backside signal carrier and/or a VDD and a VSS signal carrier and/or have different electrical potentials.

In addition, as shown in FIG. 8, the semiconductor device fabrication method 800 also includes disposing a carrier wafer on a BEOL layer (block 807) and disposing a frontside contact to connect one of the first and second S/D epitaxial regions to the BEOL layer (block 808) as well as disposing the second backside metallization on a backside interconnect layer (block 809) and disposing connection metallization to connect the first and second backside metallization (block 810).

In accordance with one or more embodiments, the opening of the contact cut of block 804 can include opening the contact cut at a location which is in line with the second S/D epitaxial region (block 8041) by, for example, forming an alignment mark at a known distance from the center of the second S/D epitaxial region (block 80411) and identifying the center of the second S/D epitaxial region through intervening layers (i.e., a metallization layer and/or a hard mask layer) by reference to the alignment mark (block 80412).

As shown in FIG. 9, a secondary semiconductor device structure 901 is provided in a secondary stage of assembly following frontside substrate removal processes, backside ILD deposition to form backside ILD 910, chemical mechanical polishing (CMP), backside contact patterning executed with respect to the initial semiconductor device structure 401 of FIG. 4 as well as subsequent removal of the placeholder elements 441 of FIG. 4, initial backside contact formation to form first backside contact 920 and deposition of first backside metallization 930. The first backside contact 920 is disposed to electrically connect the first S/D epitaxial region 461 of FIG. 4 and the first backside metallization 930 to one another.

As shown in FIG. 10, a tertiary semiconductor device structure 1001 is provided in a tertiary stage of assembly following deposition of backside ILD 1010 and backside contact patterning executed with respect to the secondary semiconductor device structure 901 of FIG. 9. The backside contact patterning forms a contact opening 1020 through the backside ILD 1010, through the first backside metallization 930 and through a portion of the first backside contact 920. A location of the backside contact patterning and the contact opening 1020 can be established by reference to an alignment mark as described above with reference to the upper and lower images of FIG. 5.

As shown in FIG. 11, a fourth semiconductor device structure 1101 is provided in a fourth stage of assembly following deposition of dielectric material to form a dielectric liner 1110 along sidewalls of the contact opening 1020 executed with respect to the tertiary semiconductor device structure 1001 of FIG. 10.

The semiconductor device 101 of FIG. 7 can subsequently be arrived at by formation of the second backside contact 750 as well as formation of the second backside metallization 735 to which the second backside contact 750 is connected, formation of the backside interconnect layer 780 on which the second backside metallization 735 is disposed and formation of the connection metallization 782 to electrically connect the first backside metallization 730 and the backside interconnect layer 780 executed with respect to the fourth semiconductor device structure 1101 of FIG. 11.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
an active region;
first, second and third gate regions disposed across the active region;
a first source/drain (S/D) epitaxial region interposed between the first and second gate regions;
a second S/D epitaxial region interposed between the second and third gate regions;
backside metallization;
a first backside contact to connect the first S/D epitaxial region to the backside metallization;
a second backside contact to connect the second S/D epitaxial region to the backside metallization; and
backside insulation disposed to isolate the first and second backside contacts from one another.

2. The semiconductor device according to claim 1, wherein:
the first and second S/D epitaxial regions are separated by a distance of about 48-54 nm or less, and
the backside insulation comprises dielectric material centered between the first and second backside contacts.

3. The semiconductor device according to claim 1, further comprising:
a back-end-of-line (BEOL) layer;
a carrier wafer disposed on the BEOL layer; and
a frontside contact to connect one of the first and second S/D epitaxial regions to the BEOL layer.

4. The semiconductor device according to claim 1, wherein the backside metallization is one of a backside power rail (BPR) and a backside signal carrier.

5. The semiconductor device according to claim 1, wherein the backside metallization is one of a VDD and a VSS signal carrier.

6. The semiconductor device according to claim 1, further comprising:
a backside interconnect layer;
additional backside metallization disposed on the backside interconnect layer; and
connection metallization to connect the backside metallization and the additional backside metallization.

7. A semiconductor device, comprising:
an active region;
first, second and third gate regions disposed across the active region;
a first source/drain (S/D) epitaxial region interposed between the first and second gate regions;
a second S/D epitaxial region interposed between the second and third gate regions;
first backside metallization;
second backside metallization;
a first backside contact to connect the first S/D epitaxial region to the first backside metallization;
a second backside contact to connect the second S/D epitaxial region to the second backside metallization; and
backside insulation disposed to isolate the first and second backside contacts from one another.

8. The semiconductor device according to claim 7, wherein:
the first and second S/D epitaxial regions are separated by a distance of about 48-54 nm or less, and
the backside insulation comprises a dielectric liner surrounding one of the first and second backside contacts.

9. The semiconductor device according to claim 7, further comprising:
a back-end-of-line (BEOL) layer;
a carrier wafer disposed on the BEOL layer; and
a frontside contact to connect one of the first and second S/D epitaxial regions to the BEOL layer.

10. The semiconductor device according to claim 7, wherein the first and second backside metallization are each one of a backside power rail (BPR) and a backside signal carrier.

11. The semiconductor device according to claim 7, wherein the first and second backside metallization are each one of a VDD and a VSS signal carrier.

12. The semiconductor device according to claim 7, wherein the first and second backside metallization have different electrical potentials.

13. The semiconductor device according to claim 7, further comprising:
a backside interconnect layer on which the second backside metallization is disposed; and
connection metallization to connect the first backside metallization to the backside interconnect layer.

14. A semiconductor device fabrication method, comprising:
disposing first, second and third gate regions across an active region;
interposing first and second source/drain (S/D) epitaxial regions between the first and second gate regions and between the second and third gate regions, respectively;
forming an initial backside contact to connect the first and second S/D epitaxial regions to backside metallization;
opening a contact cut through the initial backside contact to reform the initial backside contact as first and second backside contacts connected to the first and second S/D epitaxial regions, respectively; and
filling the contact cut with insulation to isolate the first and second backside contacts from one another.

15. The semiconductor device fabrication method according to claim 14, wherein:
the first and second S/D epitaxial regions are separated by a distance of about 48-54 nm or less, and
the opening of the contact cut comprises opening the contact cut through a center of the initial backside contact.

16. The semiconductor device fabrication method according to claim 15, further comprising:
forming an alignment mark at a known distance from the center of the initial backside contact; and
identifying the center of the initial backside contact by reference to the alignment mark.

17. The semiconductor device fabrication method according to claim 14, further comprising:
disposing a carrier wafer on a back-end-of-line (BEOL) layer; and
disposing a frontside contact to connect one of the first and second S/D epitaxial regions to the BEOL layer.

18. The semiconductor device fabrication method according to claim 14, wherein the backside metallization is one of a backside power rail (BPR) and a backside signal carrier and/or a VDD and a VSS signal carrier.

19. The semiconductor device fabrication method according to claim 14, further comprising:
disposing additional backside metallization on a backside interconnect layer; and
disposing connection metallization to connect the backside metallization and the additional backside metallization.

20. The semiconductor device fabrication method according to claim 19, wherein the backside metallization and the additional backside metallization have different electrical potentials.
